(19) United States
(12) Patent Application Publication
(10) Pub. No.: US 2009/0231814 A1
(43) Pub. Date: Sep. 17, 2009

(54) Protective cap for thermal grease

(75) Inventors: Chin-Chun Liao, Taipei City (TW); Meng-Hung Ko, Taipei County (TW); De-Cheng Luo, Sicchuan (CN)

Correspondence Address: BACON & THOMAS, PLLC, 625 SLATERS LANE, FOURTH FLOOR, ALEXANDRIA, VA, 22314-1176, US

(73) Assignee: TAI-SOL ELECTRONICS CO., LTD., TAIPEI CITY (TW)

(21) Appl. No.: 12/213,246

(22) Filed: Jun. 17, 2008

(30) Foreign Application Priority Data
Mar. 11, 2008 (TW) 97204134

(51) Int. Cl. H05K 7/20

(52) U.S. Cl. 361/704

(57) ABSTRACT

A protective cap for thermal grease of a heat sink includes a sheet member having a main concavity recessed downward from a center thereof; and four corner concavities recessed downward from four corners located a periphery of the main concavity respectively. Each of at least two of the corner concavities has an interference hole formed at a bottom sidewall thereof. The interference holes are to be interference fit with respective screw bolts located at the bottom side of the heat sink to fasten the sheet member, whereby the thermal grease located at a bottom side of the heat sink can be covered for protection.

### BACKGROUND OF THE INVENTION

1. Field of the Invention

The present invention relates generally to heat-dissipating devices, and more particularly, to a protective cap for thermal grease of a heat sink.

2. Description of the Related Art

A conventional protective cap for thermal grease of a heat sink as disclosed in U.S. Pat. No. 6,049,458 includes a cover having a cavity and adhesively mounted to a bottom side of the heat sink. Thermal grease on the heat sink is surrounded in the cavity of the cover to be protected and to avoid dust.

Because the conventional protective cap is adhesively mounted to the heat sink, however, the cover may accidentally disengage from the heat sink due to deficient adhesiveness. In addition, after the cover is removed from the heat sink, there may be some unnecessary adhesive remaining on the bottom side of the heat sink.

### SUMMARY OF THE INVENTION

The primary objective of the present invention is to provide a protective cap, which protects thermal grease disposed on a bottom side of a heat sink.

The secondary objective of the present invention is to provide a protective cap, which can be fixed to a bottom side of the heat sink without adhesive.

The foregoing objectives of the present invention are attained by the protective cap composed of a sheet member. The sheet member includes a main concavity recessed downward from a center thereof; and four corner concavities recessed downward from four corners located a periphery of the main concavity respectively. Each of at least two of the corner concavities has an interference hole formed at a bottom sidewall thereof. The interference holes are to be interference fit with respective screw bolts located at the bottom side of the heat sink to fasten the sheet member.

### BRIEF DESCRIPTION OF THE DRAWINGS

FIG. 1 is a perspective view of a preferred embodiment of the present invention.

FIG. 2 is a perspective view of the preferred embodiment of the present invention that is upside-down.

FIG. 3 is a perspective view of the preferred embodiment of the present invention that is being combined with a heat sink.

FIG. 4 is a perspective view of the preferred embodiment of the present invention combined with the heat sink.

### DETAILED DESCRIPTION OF PREFERRED EMBODIMENTS

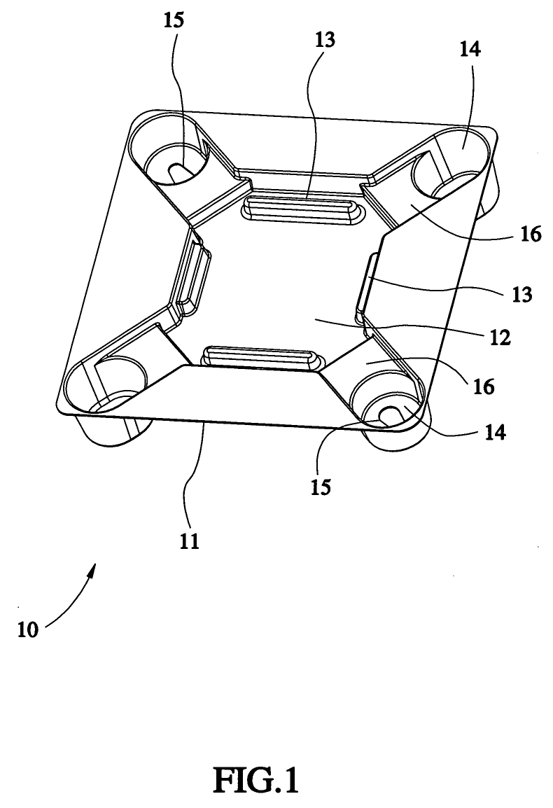

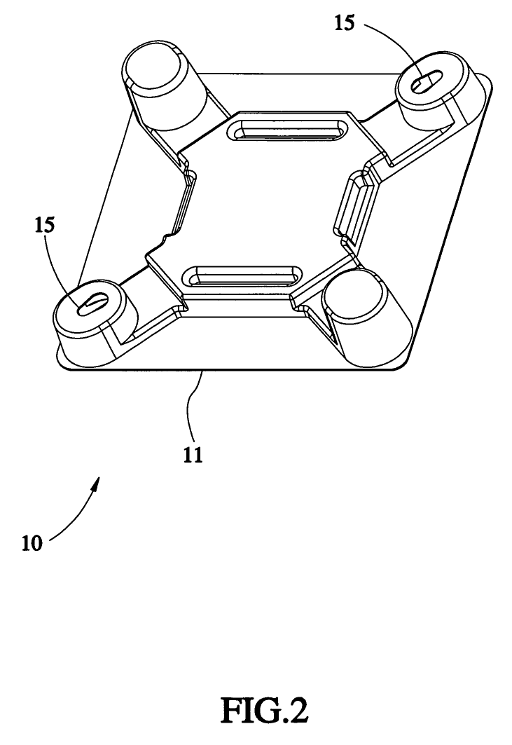

Referring to FIGS. 1-2, a protective cap 10 for thermal grease of a heat sink in accordance with a preferred embodiment of the present invention is composed of a sheet member 11.

The sheet member 11 includes a main concavity 12 recessed downward from a center thereof, four corner concavities 14 recessed downward from four corners located a periphery of the main concavity 12, four intercommunication concavities 16 recessed downward therefrom and located between the main concavity 12 and the corner concavities 14 respectively, and a plurality of protective ridges 13 protruding upward from a bottom side of the main concavity 12. An interference hole 15 is formed at a bottom sidewall of each of at least two corner concavities 14. The at least two interference holes 15 are located at diagonal ones of the corner concavities 14 respectively. Each of the intercommunication concavities 16 is less deep than the corner concavity 14 and than the main concavity 12. The protective ridges 13 are located at least two sides in the main concavity 12. In this embodiment, the protective ridges 13 are located at four sides in the main concavity 12. A top side of each of the protective ridges 13 is as high as a bottom side of the intercommunication concavity 16.

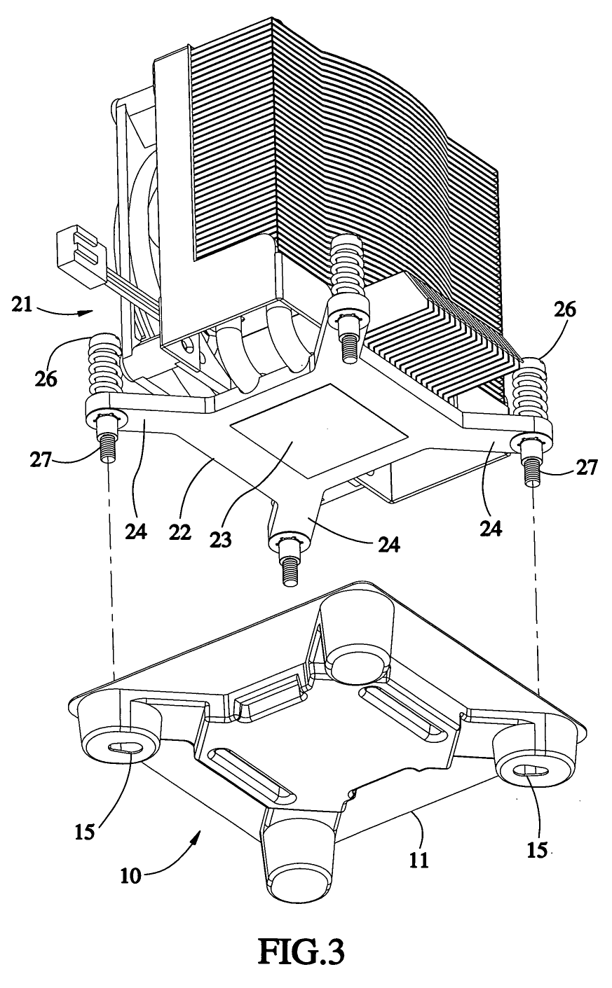

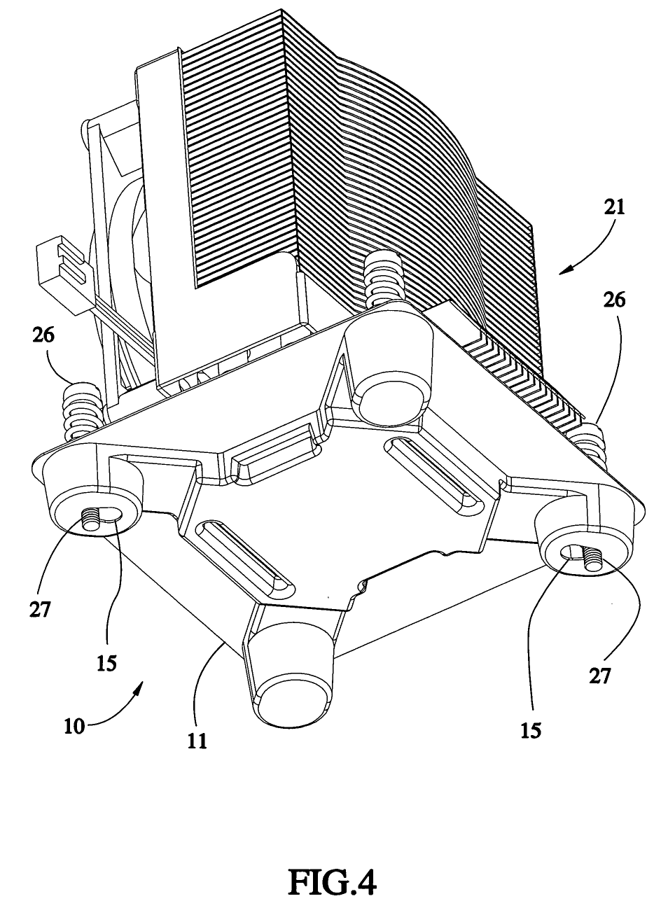

Referring to FIGS. 3 and 4 in view of FIG. 1, the protective cap 10 of the present invention is in coordination with a heat sink 21. The heat sink 21 includes a heat-dissipating plate 22 at a bottom side thereof, a rectangular layer of thermal grease 23 disposed on a central part of a bottom side of the heat-dissipating plate 22, and four extension parts 24 extending outward from four corners of the heat-dissipating plate 22 respectively. A screw bolt 26 is inserted through each of respective distal ends of the extension parts 24. Each of the screw bolts 26 has a thread 27 at a distal end thereof. After the protective cap 10 is covered to the bottom side of the heat-dissipating plate 22, the screw bolts 26 are located in the corner concavities 14 and inserted through the interference holes 15 respectively, the threads 27 interfering with the interference holes 15 respectively, such that the protective cap 10 is fixed to the heat sink 21 by interference fit.

After the protective cap 10 is fixed to the heat sink 21, the protective ridges 13 are stopped against the bottom side of the heat-dissipating plate 22. Because the protective ridges 13 are located at lateral sides of the heat-dissipating plate 22, they will not touch the thermal grease 23 and the intercommunication concavities 16 are stopped against respective bottom sides of the extension parts 24. In the meantime, the bottom sides of the extension parts 24 are partially covered by the intercommunication concavities 16 and the bottom side of the heat-dissipating plate 22 is also partially covered by the main concavity 12.

When the protective cap 10 of the present invention is mounted to the heat sink 21, the thermal grease 23 can be protected in the main concavity 12. The protective cap 10 is fixed to the heat sink 21 in such a way that the screw bolts 26 interfere with the interference holes 15 respectively. The protective ridges 13 keep the space in the main concavity 12 intact and prevent the deformed structure incurred by an external force from damage to the thermal grease 23.

In conclusion, the present invention includes the following advantages.

1. The protective cap of the present invention can be covered to the bottom side of the heat sink to provide good protection for the thermal grease.

2. The protective cap of the present invention is fixed to the bottom side of the heat sink by the interference fit between the screw bolts and the interference holes without any adhesive, such that it prevents the bottom side of the heat sink from unnecessary remnant substance.

Although the present invention has been described with respect to a specific preferred embodiment thereof, it is no way limited to the details of the illustrated structures but changes and modifications may be made within the scope of the appended claims.

What is claimed is:

1. A protective cap for thermal grease, comprising a sheet member having a main concavity recessed downward from a center thereof, four corner concavities recessed downward from four corners of a periphery of said main concavity, and an interference hole formed at each of bottom sidewalls of at least two of said corner concavities.

2. The protective cap as defined in claim 1, wherein said sheet member comprises a plurality of intercommunication concavities recessed downward therefrom and located between said main concavity and said corner concavities respectively.

3. The protective cap as defined in claim 2, wherein each of said intercommunication concavities is less deep than said corner concavity and than the main concavity.

4. The protective cap as defined in claim 2, wherein said sheet member further comprises a plurality of protective ridges protruding upward from a bottom side of said main concavity, said protective ridges being located at least two lateral sides in said main concavity.

5. The protective cap as defined in claim 4, wherein each of said protective ridges at a top side thereof is as high as said intercommunication concavity at a bottom side thereof.

6. The protective cap as defined in claim 1, wherein said sheet member comprises a plurality of protective ridges protruding upward from a bottom side of said main concavity, said protective ridges being located at least two lateral sides in said main concavity.

7. The protective cap as defined in claim 1, wherein said at least two interference holes are located at diagonal ones of said corner concavities.
